(19) United States
(12) Patent Application Publication
(10) Pub. No.: US 2017/0207411 A1
(43) Pub. Date: Jul. 20, 2017

(54) OPTOELECTRONIC COMPONENT AND METHOD FOR MANUFACTURING THE SAME

(71) Applicant: Osram OLED GmbH, Regensburg (DE)

(72) Inventors: Egbert Hoefling, Regensburg (DE); Simon Schicktanz, Regensburg (DE)

(21) Appl. No.: 15/323,987

(22) PCT Filed: Jul. 31, 2015
(86) PCT No.: PCT/EP2015/067736

§ 371 Date: Jan. 5, 2017

(30) Foreign Application Priority Data
Aug. 8, 2014 (DE) 10 2014 111 345.4

(51) Int. Cl. H01L 51/52; H01L 51/56

(52) U.S. Cl. CPC H01L 51/5228; H01L 51/5212; H01L 51/56; H01L 51/5268; H01L 51/5253

(57) ABSTRACT

An optoelectronic component includes a first electrically conductive contact layer, an electrically insulating layer above the first electrically conductive contact layer, a second electrically conductive contact layer above the electrically insulating layer, a first electrically conductive electrode layer above the second electrically conductive contact layer, at least one optically functional layer structure above the first electrically conductive electrode layer, and a second electrically conductive electrode layer above the optically functional layer structure, wherein the second electrically conductive contact layer has a first cutout, the electrically insulating layer has a second cutout, which overlaps the first cutout, an electrically conductive plated-through hole is arranged in the first cutout and in the second cutout, said electrically conductive plated-through hole being led to the first electrically conductive contact layer, and the electrically conductive plated-through hole is electrically insulated with respect to the second electrically conductive contact layer.

### RELATED APPLICATIONS

The present application is a national stage entry according to 35 U.S.C. §371 of PCT application No.: PCT/EP2015/067736 filed on Jul. 31, 2015, which claims priority from German application No.: 10 2014 111 345.4 filed on Aug. 8, 2014, and is incorporated herein by reference in its entirety.

### TECHNICAL FIELD

Various embodiments relate to an optoelectronic component including at least one optically functional layer structure, and to a method for manufacturing such an optoelectronic component.

### BACKGROUND

Optoelectronic components which emit light can be, for example, light emitting diodes (LEDs) or organic light emitting diodes (OLEDs). An OLED may include an anode and a cathode with an organic functional layer system therebetween. The organic functional layer system may include one or a plurality of emitter layers in which electromagnetic radiation is generated, a charge generating layer structure composed of in each case two or more charge generating layers (CGL) for charge generation, and one or a plurality of electron blocking layers, also designated as hole transport layers (HTL), and one or a plurality of hole blocking layers, also designated as electron transport layers (ETL), in order to direct the current flow.

The organic functional layer system, on account of its sensitivity to moisture, requires a protective layer, for example an electrically insulating thin-film encapsulation deposited over the whole area. Said protective layer usually makes it more difficult to provide a mechanically stable and electrically highly conductive connection of the optoelectronic component to a system in which the optoelectronic component is operated. Precisely optoelectronic components which include organic layers, such as, for example, organic light emitting diodes, organic solar cells or organic sensors, require an as mechanically stable and electrically highly conductive external connection as possible.

On account of the high sensitivity exhibited by optoelectronic components based on organic layers, for as cost-effective manufacture as possible it is necessary to electro-optically measure the optoelectronic components directly after their production, in particular after the deposition of the thin-film encapsulation. In particular, additional costs that arise in the event of further processing of possibly deficient or even defective optoelectronic components can be avoided as a result.

A plurality of optoelectronic components, for example LEDs and/or OLEDs, are often combined together to form an optoelectronic assembly and operated jointly. In this case, it is advantageous to enable a plurality of optoelectronic components to be arranged as far as possible without margins. In this case, passive marginal regions of the individual optoelectronic components are intended to be kept as small as possible. A high filling factor of the optoelectronic assembly with optoelectronic components is advantageously made possible as a result.

Conventionally it is known for optoelectronic components to be electrically and mechanically connected externally via metalized contact areas. Such metalized contact areas usually cover areas in the marginal region of the optoelectronic component. For the external electrical connection of the known optoelectronic components, the thin-film encapsulation, normally deposited over the whole area, is removed by means of laser ablation, for example. Afterward, solderable contacts are formed by, for example, ACF bonding, (US) soldering, (US) welding or adhesive bonding for example of a flexible printed circuit board, of a metal strip or of a cable. In this case, however, it is disadvantageous that an additional interface forms which increases the contact resistance of the optoelectronic component and can thus disadvantageously reduce the efficiency of the optoelectronic component. Moreover, there is the risk of the mechanical stability of the optoelectronic component decreasing as a result of the additional interface.

Conventional optoelectronic components furthermore have the disadvantage that normally, on account of their electrically insulating thin-film encapsulation deposited over the whole area, they are not electrically contactable directly after their production. It is thus disadvantageous that it is not possible to electro-optically test the functionality of the optoelectronic components within a close time frame in the production method. As a result, electro-optical failures of the optoelectronic components are processed further without being discovered after their manufacture, which disadvantageously causes additional manufacturing costs.

Furthermore, the contact areas conventionally used for external electrical connection proportionally reduce an active region of the optoelectronic components and disadvantageously prevent a plurality of optoelectronic components from being arranged without margins laterally alongside one another to form an optoelectronic assembly. Active region of the optoelectronic component should be understood to mean, in particular, the region which is suitable and/or provided for radiation emission and/or radiation detection.

### SUMMARY

Various embodiments specify an optoelectronic component which has the highest possible efficiency and/or which has a high mechanical stability and/or which is distinguished in particular by the active region constituting the highest possible proportion of the total area of the optoelectronic component, and/or which makes it possible, in particular, for a plurality of optoelectronic components to be arranged alongside one another as far as possible without margins.

Furthermore, various embodiments specify a method for manufacturing an optoelectronic component which can be carried out simply and/or cost-effectively, and/or which makes it possible, in particular, to identify deficient and/or defective optoelectronic components at an early stage in the manufacturing sequence.

Various embodiments are achieved in accordance with one aspect of the present disclosure by means of an optoelectronic component including a first electrically conductive contact layer, an electrically insulating layer above the first electrically conductive contact layer, a second electrically conductive contact layer above the electrically insulating layer, a first electrically conductive electrode layer above the second electrically conductive contact layer, at least one optically functional layer structure above the first electrically conductive electrode layer, and a second electrically conductive electrode layer above the optically functional layer structure. The second electrically conductive contact layer has a first cutout. The electrically insulating layer has a second cutout, which overlaps the first cutout. An electrically conductive plated-through hole is arranged in the first cutout and in the second cutout, said electrically conductive plated-through hole being led to the first electrically conductive contact layer. The electrically conductive plated-through hole is electrically insulated with respect to the second electrically conductive contact layer.

The optoelectronic component accordingly includes in its construction a layer stack having layers arranged one above another. The first electrically conductive contact layer, the electrically insulating layer and the second electrically conductive contact layer serve in particular as a carrier layer structure. The first electrically conductive electrode layer, the optically functional layer structure and the second electrically conductive electrode layer may serve as an optoelectronic structure.

In particular, the first electrically conductive contact layer extends in a lateral direction on a side of the electrically insulating layer facing away from the optoelectronic structure. The second electrically conductive contact layer likewise extends in a lateral direction on a side of the electrically insulating layer facing the optoelectronic structure. The carrier layer structure is thus formed by a multilayer construction, wherein the first cutout, the second cutout and the plated-through hole at least partly pass through the layers in a vertical direction.

The individual layers of the carrier layer structure, in particular the first electrically conductive contact layer, the electrically insulating layer and the second electrically conductive contact layer, may extend over approximately the entire lateral extent of the optoelectronic component. By way of example, the individual layers extend over more than 90%, more than 95%, for example—apart from the cutouts and/or the insulation—over 100%, of the lateral extent of the entire optoelectronic component.

The electrically conductive plated-through hole introduced in the first cutout and the second cutout in the carrier layer structure serves, inter alia, for electrically contacting the optoelectronic structure. Consequently, in contrast to conventional practice, the electrical connection to the optoelectronic structure is not provided via contact areas in the marginal region of the optoelectronic component. In particular, the electrical connection is at least partly integrated in the carrier layer structure in the present case on account of the electrically conductive plated-through hole. The electrical connection through the corresponding layers of the carrier layer structure can also be formed by means of two or more plated-through holes. In particular, the optoelectronic component may include two or more plated-through holes in corresponding cutouts by means of which an electrically conductive electrode layer is electrically coupled to the corresponding electrically conductive contact layer.

This integrated electrically conductive connection of the optoelectronic structure advantageously makes it possible to increase the efficiency of the optoelectronic component on account of the smallest possible number of electrical interfaces in the electrical connection. In particular, the integrated electrically conductive connection has a low electrical contact resistance. The electrically conductive connection integrated into the carrier layer structure furthermore advantageously has a high mechanical tensile strength and thus advantageously increases the mechanical stability of the optoelectronic component. Moreover, the present optoelectronic component is distinguished by the largest possible area of the active region on account of the integrated electrically conductive connection, in particular on account of contact areas being absent in the marginal region of the optoelectronic structure. This furthermore enables a plurality of optoelectronic components to be arranged alongside one another virtually without margins, for example in order to provide an optoelectronic assembly including a plurality of optoelectronic components arranged laterally adjacent to one another.

The optoelectronic structure is provided for making it possible to convert electrically generated data or energies into light emission, or vice versa. By way of example, the optoelectronic structure is an OLED, an organic solar cell or an organic sensor.

The electrically conductive plated-through hole may completely fill the first cutout and the second cutout in a vertical direction. The second electrically conductive contact layer thus has level and planar main surfaces, wherein the optoelectronic structure is arranged on the side of one main surface and the electrically insulating layer is arranged on the side of the other main surface. Likewise, the electrically insulating layer may have level and planar main surfaces, wherein the first electrically conductive contact layer is arranged on the side of one main surface and the second electrically conductive contact layer is arranged on the side of the other main surface. To put it another way, the plated-through hole is monolithically integrated in the layers of the carrier layer structure. “Monolithic integration” is regarded, in particular, as a cohesive transition and/or a flush arrangement of two components and/or absent terminal elements, connection elements, plugs or soldered contacts between the two components.

In accordance with one development, the first electrically conductive electrode layer is electrically conductively connected to the second electrically conductive contact layer. The second electrically conductive electrode layer is electrically conductively connected to the first electrically conductive contact layer via the electrically conductive plated-through hole.

A first electrical connection of the optically functional layer structure is accordingly formed via the first electrically conductive electrode layer and the second electrically conductive contact layer, which for example are arranged one directly above the other and are thus directly in electrical and mechanical contact. A second electrical connection of the optically functional layer structure is formed via the plated-through hole through layers of the carrier layer structure. A simple and yet mechanically stable electrical connection having a low electrical contact resistance is thus advantageously provided.

In accordance with one development, the electrically conductive plated-through hole and the second electrically conductive electrode layer are formed in an integral fashion. In various embodiments, the electrically conductive plated-through hole and the second electrically conductive electrode layer are in direct contact with one another. An integral formation should be understood to mean, in particular, that the electrically conductive plated-through hole and the second electrically conductive electrode layer are composed of the same material and/or are applied in a common method step and/or a transitionless connection of both components is provided. The integral formation advantageously enables the mechanical stability and the low electrical contact resistance to be improved further.

In accordance with one development, the first electrically conductive contact layer, the electrically insulating layer and the second electrically conductive contact layer are formed as a film laminate. In particular, the carrier layer structure including, as in the present case, a plurality of films stacked one above another in a planar manner is distinguished by its particularly small thickness and/or its flexible mechanical property. In various embodiments, the film laminate has a thickness in a range of between 2 μm and 1000 μm inclusive, which may be between 10 μm and 500 μm inclusive, and may particularly be between 50 μm and 200 μm inclusive. The film laminate may have a flexural strength from non-bent up to a bending radius of for example 500 mm, of for example 20 mm, of for example 1 mm.

Alternatively, it is possible for the carrier layer structure to be formed from a film metalized on both sides, for example a plastics film. As a further alternative, it is possible for the carrier layer structure to be formed from a metal film above which is applied an insulating layer and/or a lacquer layer above which a metalization is in turn applied.

In accordance with one development, a lacquer layer for electrical insulation is arranged between the electrically conductive plated-through hole and the second electrically conductive contact layer. Such a lacquer layer enables a simple and space-saving electrical insulation in the region of the first cutout of the second electrically conductive contact layer. In particular, inner walls of the first cutout have the lacquer layer. In other words, the inner walls of the first cutout are coated with the lacquer layer, such that a direct electrical contact between the electrically conductive plated-through hole and the second electrically conductive contact layer is prevented.

In accordance with one development, a buffer layer is arranged between the second electrically conductive contact layer and the first electrically conductive electrode layer, said buffer layer advantageously having a planarizing and/or encapsulating function. For electrical connection between the second electrically conductive contact layer and the first electrically conductive electrode layer, the buffer layer may have a feedthrough in which an electrically conductive material is introduced.

In accordance with one development, a thin-film encapsulation is arranged on the second electrically conductive electrode layer. Such a thin-film encapsulation advantageously protects moisture-sensitive, in particular organic, layers of the component. The thin-film encapsulation may be deposited over the whole area and electrically insulating. Moreover, a thin-film encapsulation can be arranged on inner walls of the first cutout and/or the second cutout, for example in the form of an ALD coating. A moisture barrier in particular relative to the electrically insulating layer, for example the plastics film, is advantageously formed as a result.

In accordance with one development, the first electrically conductive contact layer has a third cutout. The electrically insulating layer has a fourth cutout, which overlaps the third cutout. In the third cutout and in the fourth cutout an external electrically conductive connection is led to the second electrically conductive contact layer, which is electrically insulated with respect to the first electrically conductive contact layer.

To put it another way, the embedded, second electrically conductive contact layer of the carrier layer structure is exposed by means of the third and fourth cutouts through the lower layers of the carrier layer structure such that the second electrically conductive contact layer is electrically contactable from an underside.

The electrical contacting from the underside of the carrier layer structure advantageously enables an external electrical contacting directly after the production of the optoelectronic component. Removing the thin-film encapsulation for the purpose of external contacting is advantageously obviated. Directly after production means, in particular, before separating the optoelectronic component from an assemblage to form an individual component and/or before at least regionally removing the thin-film encapsulation. An external electrical contacting at an early stage in comparison with conventional optoelectronic components is advantageously made possible. Failures in the optoelectronic components can thus be identified at an early stage in the manufacturing sequence, as a result of which, in the case of a failure, further process steps such as, for example, for manufacturing a suitable contact interface to an overall system and additional costs caused thereby are obviated.

In accordance with one development, the optoelectronic component includes at least one third electrically conductive electrode layer above the second electrically conductive electrode layer, at least one third electrically conductive contact layer above the second electrically conductive contact layer, at least one second electrically insulating layer between the second electrically conductive contact layer and the third electrically conductive contact layer, at least one further cutout and at least one further electrically conductive plated-through hole.

To put it another way, the optoelectronic layer structure includes a plurality of electrode layers stacked one above another and may include a plurality of optically functional layer structures stacked one above another. The carrier layer structure includes a plurality of electrically conductive contact layers stacked one above another, which are electrically insulated from one another in each case by means of an electrically insulating layer. For electrically connecting the electrically conductive electrode layers to the respective assigned electrically conductive contact layer, corresponding cutouts and in each case a plated-through hole led therein may be formed in the individual layers of the carrier layer structure.

By means of this plurality of stacked layers of the carrier layer structure, advantageously a plurality of optically functional layer structures can be electrically contacted independently of one another in a simple and mechanically stable manner.

In accordance with one development, at least one of the electrically conductive electrode layers and/or the optically functional layer structure are/is laterally segmented, and the carrier layer structure includes, vertically one above another, a plurality of electrically conductive contact layers, electrically isolated from one another, for electrically contacting the individual segments arranged laterally alongside one another. For the purpose of electrical insulation, electrically insulating layers are formed between the individual electrically conductive contact layers.

By way of example, the optoelectronic component has a segmentation, in particular a plurality of OLED elements. The OLED elements can for example be electrically connected in parallel and/or share at least one common electrode. By way of example, two OLED elements include the same first electrically conductive electrode layer, but have optically functional layer structures that are separated from one another and segments of the second electrically conductive electrode layer that are correspondingly separated from one another, which are electrically conductively connected in each case to contact layers that are arranged one above another and are separated from one another.

In accordance with one development, at least one of the electrically conductive contact layers for electrical contacting is assigned to each electrode layer and is electrically connected thereto. In other words, at least one of the electrically conductive contact layers of the carrier layer structure may be assigned to each OLED segment and/or to each electrically conductive electrode layer. In this case, at least one plated-through hole connects each electrically conductive contact layer separated by an electrically insulating layer to the assigned electrode layer of the respective OLED segment. It is also possible for a plurality of plated-through holes to be assigned to an OLED segment. In other words, one or a plurality of segments can have in each case two or more plated-through holes.

Electrical connections of the optoelectronic components that are formed in this way advantageously make it possible to minimize passive marginal regions of the optoelectronic components to such an extent that it is possible for a plurality of optoelectronic components to be arranged alongside one another virtually without margins. For example, if a plurality of optoelectronic components are arranged laterally alongside one another to form an optoelectronic assembly, an optoelectronic assembly having the smallest possible lateral extent can thus be realized. With the aid of an appropriately designed baseplate, which can optionally include magnetized regions, an electrical and mechanical connection of the individual optoelectronic components in regard to the optoelectronic assembly can be produced in a particularly simple manner. For this purpose, the baseplate may have appropriate electrically conductive mating contacts at exposed locations of the underside of the carrier layer structure at which the respective cutouts and plated-through holes are formed.

If the baseplate includes magnetized regions, the electrically conductive contact layers of the carrier layer structure may be magnetizable. This advantageously enables a simple electrical and mechanical fixing of the optoelectronic component on the baseplate.

In accordance with one development, lateral terminals for an electrical and/or mechanical connection are integrated in the carrier layer structure. The lateral terminals may be formed by means of laser cutting. The lateral terminals can be mechanically coded in accordance with their polarity or assignment to the respective optoelectronic component or OLED segment and/or have a latching function and/or be bent, which may be downward or upward. The coding and/or latching function advantageously prevent(s) polarity reversal and/or enable(s) a simple plug connection. The bent lateral terminals advantageously enable a plurality of optoelectronic components to be arranged alongside one another virtually without margins.

The object is furthermore achieved by means of a method for manufacturing an optoelectronic component, in which a first electrically conductive contact layer is formed, an electrically insulating layer is formed above the first electrically conductive contact layer, a second electrically conductive contact layer is formed above the electrically insulating layer, a first cutout is formed in the second electrically conductive contact layer, a second cutout is formed in the electrically insulating layer, which overlaps the first cutout, an electrically conductive plated-through hole is formed in the first cutout and in the second cutout. The electrically conductive plated-through hole is electrically conductively connected to the first electrically conductive contact layer and is electrically insulated from the second electrically conductive contact layer. Furthermore, a first electrically conductive electrode layer is formed above the second electrically conductive contact layer, at least one optically functional layer structure is formed above the first electrically conductive electrode layer, and a second electrically conductive electrode layer is formed above the optically functional layer structure.

In other words, a layer stack including layers arranged one above another is formed in the present case. In this case, between applying the individual layers, at least in part the cutouts and the plated-through hole are formed in individual layers provided. This advantageously enables at least one electrically conductive connection integrated in the layers. A mechanically stable and simply produced electrically conductive connection is advantageously made possible. Moreover, an electrically conductive connection that saves as much space as possible is thus provided, thus enabling, inter alia, a plurality of optoelectronic components produced in this way to be arranged as closely as possible.

Moreover, the integrated electrically conductive connection enables an external electrical connection directly after the production of the optoelectronic component. At least regional removal of a thin-film encapsulation for external electrical connection is advantageously obviated. Failures of the optoelectronic components produced can thus be ascertained at an early stage in the manufacturing sequence, as a result of which further processing of said failures and unnecessary further costs caused thereby can be prevented. The production method can accordingly be carried out in a simple and/or cost-effective manner, and/or enables early identification of deficient and/or defective optoelectronic components.

In accordance with one development, the first cutout and the second cutout are formed simultaneously, in particular in a common method step. An overlap of the first cutout and the second cutout is thus advantageously ensured.

In accordance with one development, the cutouts, in particular in the electrically insulating layer, are formed by means of mechanical drilling, laser drilling or a photochemical method. Such methods are known to the person skilled in the art and are therefore not discussed in any greater detail at this juncture. Furthermore, these methods enable the cutouts to be produced in a simple, precise and/or cost-effective manner.

In accordance with one development, the second electrically conductive electrode layer and the electrically conductive plated-through hole are formed simultaneously, in particular in a common method step. In particular, the second electrically conductive electrode layer and the electrically conductive plated-through hole are thus formed from the same material and have an integral configuration. This advantageously reduces the number of electrical interfaces, as a result of which the contact resistance is advantageously reduced.

In accordance with one development, the first electrically conductive contact layer, the electrically insulating layer and the second electrically conductive contact layer are formed by the electrically insulating layer being provided and the first electrically conductive contact layer and the second electrically conductive contact layer being formed, which may be coated, on both sides on the electrically insulating layer. In the present case, the carrier layer structure is formed for example by an electrically insulating layer coated on both sides, for example by a plastics film metalized on both sides. A simple and/or uncomplicated production of the carrier layer structure is thus made possible.

In accordance with an alternative development, the first electrically conductive contact layer, the electrically insulating layer and the second electrically conductive contact layer are formed by one of the electrically conductive contact layers being provided and the electrically insulating layer being formed on said one electrically conductive contact layer provided. The other of the electrically conductive contact layers is subsequently formed on the electrically insulating layer. By way of example, the carrier layer structure is produced by means of a film lamination, for example using PSA (pressure sensitive adhesive) or liquid adhesive. A simple and/or uncomplicated production of the carrier layer structure is thus made possible.

In accordance with one development, at least one second electrically insulating layer is formed above the second electrically conductive contact layer. Furthermore, at least one third electrically conductive contact layer is formed above the second electrically insulating layer. At least one further cutout and at least one further electrically conductive plated-through hole are formed. At least one third electrically conductive electrode layer is formed above the second electrically conductive electrode layer.

In accordance with one development, at least one of the electrically conductive electrode layers and/or the optically functional layer structure are/is laterally segmented. By way of example, the second electrically conductive electrode layer is formed over the whole area and subsequently segmented. Alternatively, the second electrically conductive electrode layer can be formed in a manner such that it is already segmented. In various embodiments, the carrier layer structure includes a plurality of unsegmented electrically conductive contact layers, electrically insulated from one another, such that a plurality of optoelectronic components and/or individual segments of the optoelectronic components can advantageously be electrically conductively connected to the carrier layer structure independently of one another. Electrically insulating layers can in each case be used for electrical insulation between the individual electrically conductive contact layers. This advantageously makes it possible, for example, to produce an optoelectronic assembly including a plurality of optoelectronic components arranged on the carrier layer structure.

Alternative embodiments and/or advantages concerning the carrier layer structure, the optically functional layer structure, the optoelectronic component, the optoelectronic assembly and/or in each case component parts thereof have already been explained further above in the application in association with the respective product and are of course used correspondingly in the production method, without being explicitly presented again here.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1A shows a lateral sectional illustration of a conventional optoelectronic component;

FIG. 1B shows a lateral sectional illustration of a conventional optoelectronic component;

FIG. 1C shows a lateral sectional illustration of a conventional optoelectronic component;

FIG. 2A shows a lateral sectional illustration of one embodiment of an optoelectronic component;

FIG. 2B shows a plan view of the carrier layer structure of the embodiment of the optoelectronic component in FIG. 2A;

FIG. 3 shows a lateral sectional illustration of one embodiment of an optoelectronic component;

FIG. 4A shows a lateral sectional illustration of one embodiment of an optoelectronic component with external contacting;

FIG. 4B shows a plan view of the baseplate of the embodiment of the optoelectronic component in FIG. 4A;

FIG. 5 shows in each case a lateral sectional illustration of one embodiment of an optoelectronic component in the production method;

FIG. 6 shows a detailed sectional illustration of a layer structure of one embodiment of an optoelectronic component.

### DETAILED DESCRIPTION

In the following detailed description, reference is made to the accompanying drawings, which form part of this description and show for illustration purposes specific embodiments in which the present disclosure can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present disclosure. It goes without saying that the features of the various embodiments described herein can be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

An optoelectronic assembly may include one, two or more optoelectronic components. Optionally, an optoelectronic assembly can also include one, two or more electronic components. An electronic component may include for example an active and/or a passive component. An active electronic component may include for example a computing, control and/or regulating unit and/or a transistor. A passive electronic component may include for example a capacitor, a resistor, a diode or a coil.

An optoelectronic component can be an electromagnetic radiation emitting component or an electromagnetic radiation absorbing component. An electromagnetic radiation absorbing component can be a solar cell or a photodetector, for example. In various embodiments, an electromagnetic radiation emitting component can be an electromagnetic radiation emitting semiconductor component and/or be formed as an electromagnetic radiation emitting diode, as an organic electromagnetic radiation emitting diode, as an electromagnetic radiation emitting transistor or as an organic electromagnetic radiation emitting transistor. The radiation can be light in the visible range, UV light and/or infrared light, for example. In this context, the electromagnetic radiation emitting component can be formed for example as a light emitting diode (LED), as an organic light emitting diode (OLED), as a light emitting transistor or as an organic light emitting transistor. In various embodiments, the light emitting component can be part of an integrated circuit. Furthermore, a plurality of light emitting components can be provided, for example in a manner accommodated in a common housing.

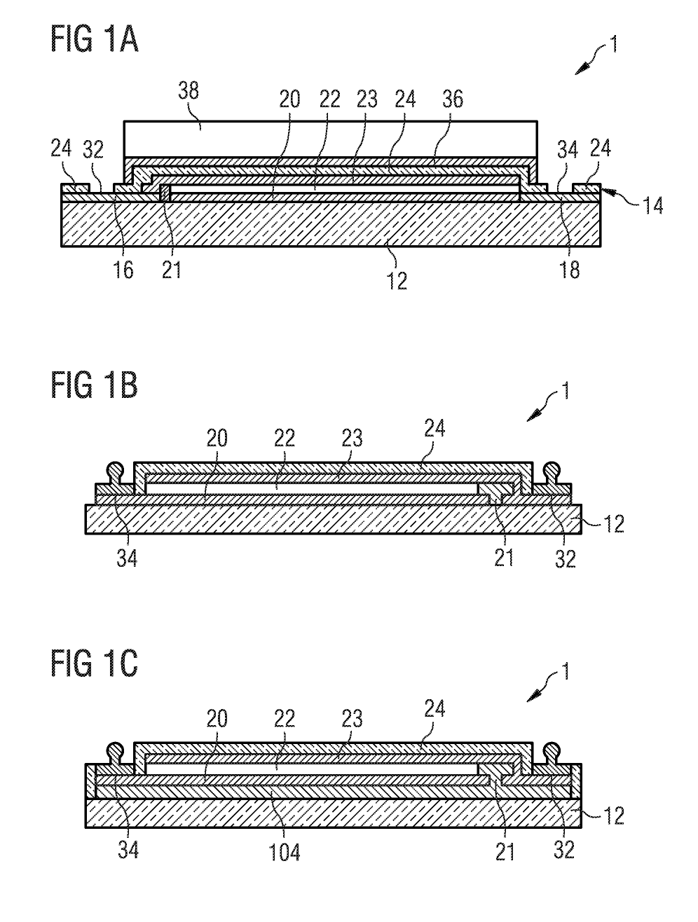

FIG. 1A shows a conventional optoelectronic component 1. The conventional optoelectronic component 1 includes a carrier 12, for example a substrate. An optoelectronic layer structure is formed on the carrier 12.

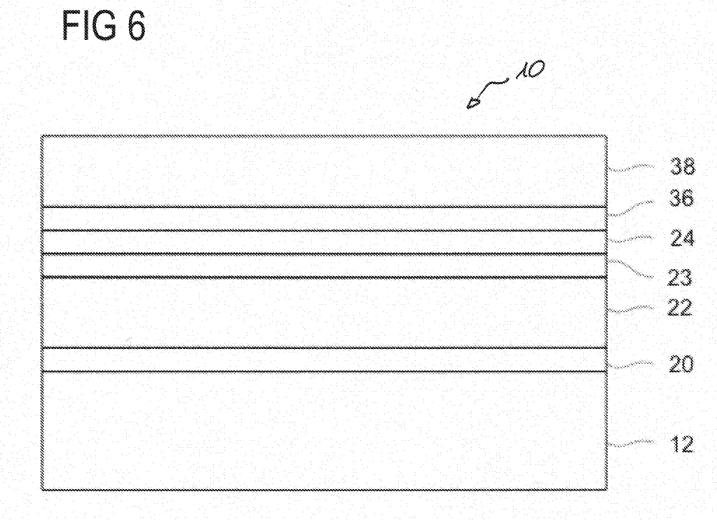

The optoelectronic layer structure includes a first electrically conductive layer 14 including a first contact section 16, a second contact section 18 and a first electrically conductive electrode layer 20. The second contact section 18 is electrically coupled to the first electrically conductive electrode layer 20 of the optoelectronic layer structure. The first electrically conductive electrode layer 20 is electrically insulated from the first contact section 16 by means of an electrical insulation barrier 21. An optically functional layer structure, for example an optically functional layer structure 22, of the optoelectronic layer structure is formed above the first electrically conductive electrode layer 20. The optically functional layer structure 22 may include for example one, two or more partial layers, as explained in greater detail further below with reference to FIG. 6. A second electrically conductive electrode layer 23 of the optoelectronic layer structure is formed above the optically functional layer structure 22, said second elastically conductive electrode layer being electrically coupled to the first contact section 16. The first electrically conductive electrode layer 20 serves for example as an anode or cathode of the optoelectronic layer structure. In a manner corresponding to the first electrically conductive electrode layer 20, the second electrically conductive electrode layer 23 serves as a cathode or anode of the optoelectronic layer structure.

An encapsulation layer, in particular a thin-film encapsulation 24, of the optoelectronic layer structure is formed above the second electrically conductive electrode layer 23 and partly above the first contact section 16 and partly above the second contact section 18, said encapsulation layer encapsulating the optoelectronic layer structure. In the thin-film encapsulation 24, a first cutout of the thin-film encapsulation 24 is formed above the first contact section 16 and a second cutout of the thin-film encapsulation 24 is formed above the second contact section 18. A first contact region 32 is exposed in the first cutout of the thin-film encapsulation 24 and a second contact region 34 is exposed in the second cutout of the thin-film encapsulation 24. The first contact region 32 serves for electrically contacting the first contact section 16 and the second contact region 34 serves for electrically contacting the second contact section 18.

An adhesion medium layer 36 is formed above the thin-film encapsulation 24. The adhesion medium layer 36 includes for example an adhesion medium, for example an adhesive, for example a lamination adhesive, a lacquer and/or a resin. A covering body 38 is formed above the adhesion medium layer 36. The adhesion medium layer 36 serves for fixing the covering body 38 to the thin-film encapsulation 24. The covering body 38 includes glass and/or metal, for example. For example, the covering body 38 can be formed substantially from glass and include a thin metal layer, for example a metal film, and/or a graphite layer, for example a graphite laminate, on the glass body. The covering body 38 serves for protecting the conventional optoelectronic component 1, for example against mechanical force actions from outside. Furthermore, the covering body 38 can serve for spreading and/or dissipating heat generated in the conventional optoelectronic component 1. By way of example, the glass of the covering body 38 can serve as protection against external actions and the metal layer of the covering body 38 can serve for spreading and/or dissipating the heat that arises during the operation of the conventional optoelectronic component 1.

The conventional optoelectronic component 1 can be singulated from a component assemblage, for example, by the carrier 12 being scribed and then broken along its outer edges illustrated laterally in FIG. 1A, and by the covering body 38 equally being scribed and then broken along its lateral outer edges illustrated in FIG. 1A. The thin-film encapsulation 24 above the contact regions 32, 34 is exposed during this scribing and breaking. Afterward, the first contact region 32 and the second contact region 34 can be exposed in a further method step, for example by means of an ablation process, for example by means of laser ablation, mechanical scratching or an etching method.

FIGS. 1B and 1C show conventional optoelectronic components and the possible external mechanical and electrical contacting thereof.

FIG. 1B shows a conventional optoelectronic component 1, which can for example largely correspond to the conventional optoelectronic component 1 explained above. The conventional optoelectronic component 1 includes the carrier 12, for example composed of glass, on which a plurality of layers of the conventional optoelectronic component 1 are applied. The first electrically conductive electrode layer 20 is formed on the carrier 12. The optically functional layer structure 22 is formed on the first electrically conductive electrode layer 20. The second electrically conductive electrode layer is formed above the optically functional layer structure 22. The thin-film encapsulation 24 is formed on the second electrically conductive electrode layer 23.

For external electrical contacting, the first contact section 32 and the second contact section 34 are formed on the carrier 12 laterally alongside the first electrically conductive electrode layer 20. The first contact section 32 is electrically conductively and mechanically connected to the second electrically conductive electrode layer 23. The second contact section 34 is correspondingly electrically conductively and mechanically connected to the first electrically conductive electrode layer 20. The insulation barrier 21 is formed for electrical insulation between the first electrically conductive electrode layer 20 and the second electrically conductive electrode layer 23, which is led, inter alia, along a side surface of the optically functional layer structure 22 in the direction of the carrier 12. The thin-film encapsulation 24, which is deposited over the whole area in the production method, is removed in the contact regions 32, 34, in which the electrical connection to the first and/or to the second electrically conductive electrode layer 20, 23 is necessary.

The external electrical and mechanical connection of the conventional optoelectronic component 1 is accordingly realized via the usually metalized contact regions 32, 34, which occupy areas in the marginal region of the conventional optoelectronic component 1. Before an external electrical connection, it is absolutely necessary to regionally remove the thin-film encapsulation 24, deposited over the whole area, for example by means of laser ablation, such that the contact regions 32, 34 are formed. Solderable external contacts such as, for example, a plug are formed generally by ACF bonding, (US) soldering, (US) welding or adhesive bonding for example of a flexible printed circuit board, a metal strip or a cable.

Such an external electrical connection can have the disadvantages that an additional electrical interface can increase the contact resistance and thus reduce the component efficiency and can potentially become mechanically unstable. Moreover, the conventional optoelectronic component 1 cannot be electrically contacted directly after its production, in particular after the deposition of the thin-film encapsulation 24, such that it may be the case that electro-optical failures are still processed further before they are identified, as a result of which additional manufacturing costs can disadvantageously arise. Furthermore, the contact regions 32, 34 can proportionally reduce an active region of the conventional optoelectronic component 1 and thus prevent a plurality of conventional optoelectronic components 1 from being arranged alongside one another without margins.

FIG. 1C shows a conventional optoelectronic component 1, which can for example largely correspond to one of the conventional optoelectronic components 1 explained above. The conventional optoelectronic component 1 includes the carrier 12, for example composed of metal. In order to ensure an electrical insulation between first electrically conductive electrode layer 20 and carrier 12, an electrically insulating buffer layer 104 is applied over the whole area on the carrier 12. As an alternative thereto, the buffer layer 104 can also cover only a partial region of the carrier 12.

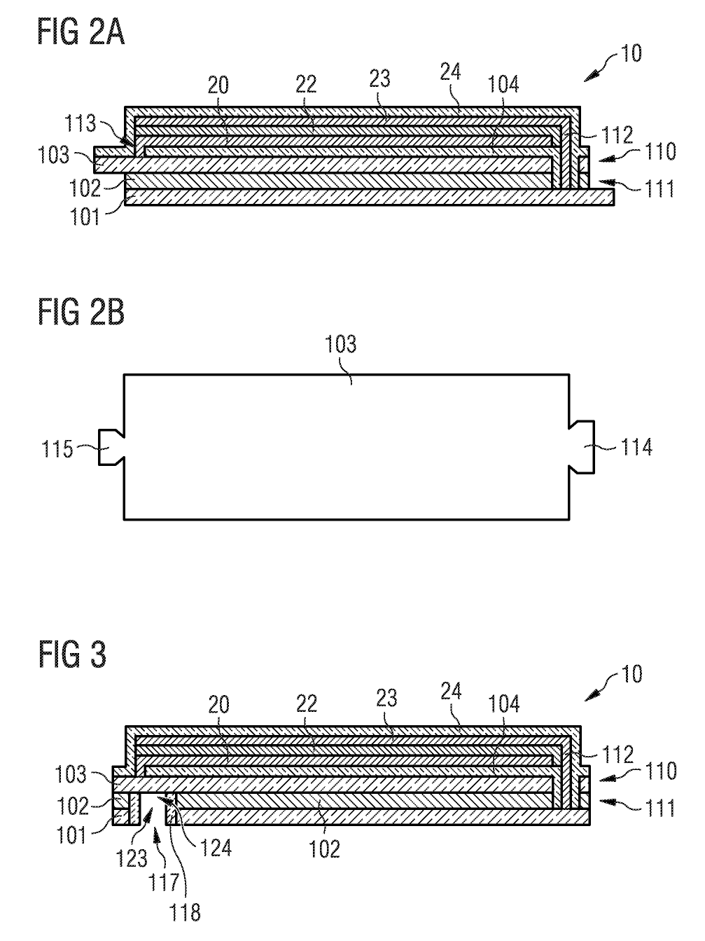

FIG. 2A shows one embodiment of an optoelectronic component 10. The optoelectronic component 10 includes the first electrically conductive electrode layer 20, the optically functional layer structure 22, the second electrically conductive electrode layer 23, the electrically insulating buffer layer 104 and the thin-film encapsulation 24.

The optically functional layer structure 22 may include for example one, two or more partial layers, as explained in greater detail further below with reference to FIG. 6. The first electrically conductive electrode layer 20 serves for example as an anode or cathode of the optoelectronic component 10. In a manner corresponding to the first electrically conductive electrode layer 20, the second electrically conductive electrode layer 23 serves as a cathode or anode of the optoelectronic component 10.

The optoelectronic component 10 furthermore includes a carrier layer structure constructed in a multilayered fashion. In particular, the carrier layer structure includes a first electrically conductive contact layer 101, an electrically insulating layer 102 formed on the first electrically conductive contact layer 101, and a second electrically conductive contact layer 103 formed on the electrically insulating layer 102, which are formed one directly above another as a layer stack. The carrier layer structure accordingly consists of two electrically conductive contact layers 101, 103 formed parallel, which are electrically isolated from one another by the electrically insulating layer 102. The layers extend laterally, in particular two-dimensionally and/or areally and/or in a plane, over a large part of the basic area of the optoelectronic component 10, for example over more than 90%, for example over more than 95%, for example—apart from the cutouts—over 100%, that is to say the total basic area, of the optoelectronic component 10.

In various embodiments, the carrier layer structure has a thickness in a range of between 2 μm and 1000 μm inclusive, which may be between 10 μm and 500 μm inclusive, and may particularly be between 50 μm and 200 μm inclusive. The carrier layer structure may have a flexural strength from non-bent up to a bending radius of for example 500 mm, of for example 20 mm, of for example 1 mm.

The second electrically conductive contact layer 103 has a first cutout 110. The electrically insulating layer 102 has a second cutout 111, which overlaps the first cutout 110, in particular is formed directly below the first cutout 110. The first cutout 110 directly transitions into the second cutout 111 in a vertical direction. The first cutout 110 and the second cutout 111 can thus be regarded as a common cutout extending through the second electrically conductive contact layer 103 and the electrically insulating layer 102.

An electrically conductive plated-through hole 112 is arranged in the first cutout 110 and in the second cutout 111. The electrically conductive plated-through hole 112 completely fills the cutouts 110, 111 in a vertical direction, in particular without margins and/or without gaps. For electrical insulation, the cutouts 110, 111 have an electrically insulating layer, for example a lacquer layer or the electrically insulating buffer layer 104, on sidewalls. The plated-through hole 112 electrically connects the first electrically conductive contact layer 101 to the second electrically conductive electrode layer 23. For this purpose, electrically conductive material of the second electrically conductive electrode layer 23 is introduced in the first and second cutouts 110, 111. The plated-through hole 112 and the second electrically conductive electrode layer 23 are thus formed in an integral fashion. The second electrically conductive contact layer 103 is electrically conductively connected to the first electrically conductive electrode layer 20, by means of a further cutout and a further plated-through hole 113 arranged therein through the buffer layer 104. For this purpose, correspondingly, electrically conductive material of the first electrically conductive electrode layer 20 may be introduced in the further cutout of the buffer layer 104 and formed in an integral fashion with the first electrically conductive electrode layer 20.

The external electrical connection of the optoelectronic component 10 is thus effected in the present case via the multilayered carrier layer structure, in which the electrically conductive contact layers 101, 103 are integrated in a manner electrically insulated from one another. In particular, the external electrical connections are monolithically integrated in the carrier layer structure.

The electrical contact routing integrated in the carrier layer structure enables an external electrical contacting from an underside of the optoelectronic component 10 directly after the production of the optoelectronic component 10. In particular, for external electrical contacting, it is not necessary to remove at least regionally the thin-film encapsulation 24 deposited over the whole area on a top side of the optoelectronic component 10. As a result, a checking with regard to functionality is made possible at an early stage in the manufacture of the optoelectronic component 10. Possible failures and/or deficiencies of the optoelectronic component 10 can thus be identified at an early stage in the manufacturing sequence. Further process steps for manufacturing a suitable external contact interface are obviated.

The carrier layer structure, in particular the first electrically conductive contact layer 101, the electrically insulating layer 102 and the second electrically conductive contact layer 103, are formed as a film laminate. That means that the individual layers of the carrier layer structure are films that are laminated one above another.

The optoelectronic component 10 is a top emitter and/or a top receiver. The optoelectronic component 10 is an OLED.

As an alternative to the optoelectronic component 10 discussed above, the optoelectronic component 10 can be segmented, in particular subdivided into a plurality of segments with electrically isolated electrode layers. In this case, at least one further electrically conductive contact layer of the carrier layer structure is assigned to each further component segment. At least one further cutout through the respective layers of the carrier layer structure connects each electrically conductive contact layer, separated by a further electrically insulating layer, to the assigned electrically conductive electrode layer.

As a further alternative to the optoelectronic component 10 discussed above, a plurality of optoelectronic components 10 can be combined and/or arranged alongside one another to form an optoelectronic assembly. On account of the external electrical connections integrated in the carrier layer structure, the passive marginal regions of the individual optoelectronic components 10 can advantageously be minimized to such an extent that it is possible for a plurality of optoelectronic components 10 to be arranged virtually without margins.

As a further alternative to the optoelectronic component 10 discussed above, the carrier layer structure can be formed from a plastics film metalized on both sides. In this case, the plastics film is provided with a metallic coating on both sides, said coating in each case forming the corresponding contact layer.

As a further alternative to the optoelectronic component 10 discussed above, the carrier layer structure can be formed from a flexible printed circuit board. A simple external electrical and/or mechanical connection of the optoelectronic component 10 is advantageously made possible as a result. As a further alternative, it is not absolutely necessary for the first cutout 110 and the second cutout 111 to merge into one another without transitions. In particular, the cutouts 110, 111 can merely overlap regionally. All that is necessary in this case is that fillings of the first and second cutouts can be formed adjacently to one another in such a way that an electrically conductive connection between second electrically conductive electrode layer 23 and first electrically conductive contact layer 101 is made possible.

In addition, two or more plated-through holes can be formed in the carrier layer structure. Said plated-through holes can serve to electrically contact the optoelectronic component 10, segments of the optoelectronic component 10 and/or a plurality of optoelectronic components 10.

As a further alternative, the adhesion medium layer can be formed above the thin-film encapsulation 24. The adhesion medium layer includes for example an adhesion medium, for example an adhesive, for example a lamination adhesive, a lacquer and/or a resin. A covering body can be formed above the adhesion medium layer. The adhesion medium layer serves for fixing the covering body to the thin-film encapsulation 24. The covering body includes glass and/or plastic, for example. For example, the covering body can be formed substantially from glass and include a thin plastics layer, for example a plastics film. The covering body serves for protecting the optoelectronic component 10, for example against mechanical force actions from outside. Furthermore, the covering body can serve for spreading and/or dissipating heat generated in the optoelectronic component 10.

As a further alternative, the optoelectronic component 10 can be singulated from a component assemblage, by the carrier layer structure being scribed and then broken along its outer edges and optionally by the covering body equally being scribed and then broken along outer edges.

FIG. 2B shows a plan view of the carrier layer structure of the optoelectronic component 10 in FIG. 2A. For external electrical and/or mechanical connection, lateral contact regions 114, 115 are integrated in the carrier layer structure. The laterally arranged contact regions 114, 115 can be mechanically coded in accordance with their polarity or assignment to the respective component segment and/or have a latching function and/or be bent downward or upward. The coding and/or latching function advantageously prevent(s) polarity reversal and/or enable(s) a simple external plug connection. Bent contact regions 114, 115 enable a plurality of optoelectronic components 10 to be arranged alongside one another virtually without margins, for example in order to provide an optoelectronic assembly.

FIG. 3 shows one embodiment of an optoelectronic component 10, which can for example largely correspond to the optoelectronic component 10 shown in FIG. 2A. The optoelectronic component 10 includes, inter alia, the first electrically conductive electrode layer 20, the optically functional layer structure 22, the second electrically conductive electrode layer 23, the electrically insulating buffer layer 104, the thin-film encapsulation 24, the cutouts 110, 111 and the electrically conductive plated-through hole 112.

In contrast to the embodiment described in FIG. 2A, in the carrier layer structure a third cutout 123 is formed in the first electrically conductive contact layer 101 and a fourth cutout 124 is formed in the electrically insulating layer 102. The third cutout 123 and the fourth cutout 124 are formed directly adjacently to one another and one directly above the other, such that the third and fourth cutouts 123, 124 together form a further cutout 117 of the carrier layer structure. This cutout 117 serves for the external electrically conductive connection of the second electrically conductive contact layer 103 from the underside of the carrier layer structure. The underside is, in particular, that side of the carrier layer structure which faces away from the optically functional layer structure. An electrically insulating layer 118 is formed on inner walls of the cutout 117, said electrically insulating layer being provided for electrically insulating the external electrically conductive connection with respect to the first electrically conductive contact layer of the carrier layer structure.

Alternative or additional embodiments of the optoelectronic component 10 have already been explained in association with the embodiment concerning FIG. 2A and are of course correspondingly used in the embodiment in FIG. 3, without being explicitly presented again here.

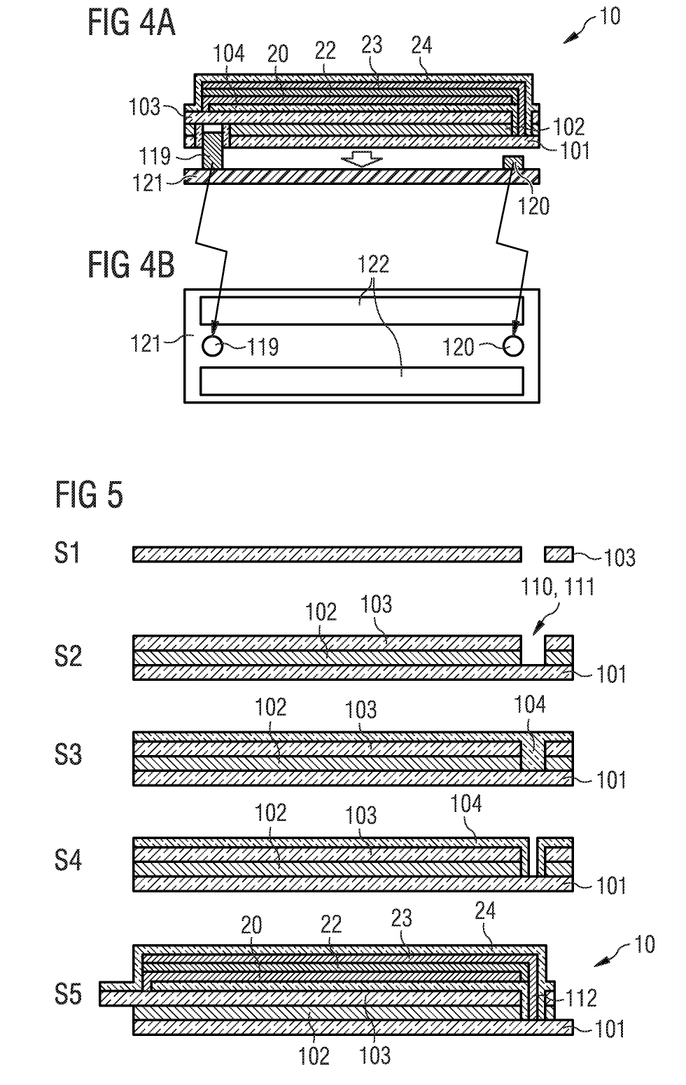

FIG. 4A shows one embodiment of an optoelectronic component 10, which largely corresponds to the optoelectronic component 10 shown in FIG. 3. The optoelectronic component 10 in FIG. 4A is provided for mechanical and electrical connection on a baseplate 121. The baseplate 121, which may be formed in an electrically insulating fashion, includes a first electrically conductive contact element 119 and a second electrically conductive contact element 120 on a mounting side, onto which the optoelectronic component 10 is mountable. The first electrically conductive contact element 119 is provided to extend into the cutout 117 of the carrier layer structure and is accordingly formed in a manner appropriately matching said cutout 117. The second electrically conductive contact element 120 serves for the external electrical connection of the first electrically conductive contact layer 101 from the underside of the carrier layer structure. The baseplate 121 accordingly has appropriate mating contacts for external electrical contacting at exposed regions of the carrier layer structure. An electrical and mechanical connection to the optoelectronic component 10 can be realized in a simple manner with the aid of the appropriately designed baseplate 121. For this purpose, the optoelectronic component 10 is bonded onto the baseplate 121.

As an alternative, the baseplate 121 can merely include the electrically conductive contact element 119, which is formed in an electrically insulated manner with respect to the baseplate 121 for example by means of an electrically insulating layer. In this case, the baseplate 121 is formed from an electrically conductive material and thus performs the function of the external contacting of the first electrically conductive contact layer 101 by directly applying the optoelectronic component 10 on the baseplate 121. The second electrically conductive contact element 120 is thus advantageously not required.

As a further alternative or in addition, the baseplate 121 may include magnetized regions 122 arranged on that side of the baseplate 121 which faces the optoelectronic component 10. The electrically conductive contact layers 101, 103 of the carrier layer structure are magnetizable in the present case, such that a particularly simple mechanical fixing of the optoelectronic component 10 on the baseplate 121 is made possible as a result.

FIG. 4B shows a plan view of the baseplate 121 of the embodiment in FIG. 4A, in particular the magnetized regions 122. In particular, FIG. 4B shows the plan view of the mounting side of the baseplate 121.

FIG. 5 shows a flow diagram of a method for manufacturing an optoelectronic component 10, for example one of the optoelectronic components 10 explained above.

The method serves to produce the optoelectronic component 10 in a simple and/or cost-effective manner. In particular, the method enables deficient and/or defective optoelectronic components 10 to be identified at an early stage in the manufacturing sequence on account of the possibility of the optoelectronic component 10 produced being externally electrically contacted from its underside at an early stage.

In a step S1, the second electrically conductive contact layer 103 is provided and structured for example by means of laser drilling, mechanical drilling or photochemical methods in such a way that the first cutout 110 is formed.

In a step S2, the electrically insulating layer 102 and the first electrically conductive contact layer 101 are applied by means of a substrate lamination, for example using PSA or liquid adhesive, on the second electrically conductive contact layer 103, such that a layer stack composed of layers of the carrier layer structure that are formed one directly above another arises. In a manner corresponding to the first cutout 110, a second cutout 111 is formed in the electrically insulating layer 102 for example by means of laser drilling, mechanical drilling or photochemical methods.

In a step S3, the electrically insulating buffer layer 104 is deposited over the whole area on the second electrically conductive contact layer 103 and in the cutouts 110, 111, for example by means of ALD. The buffer layer 104 forms a thin-film barrier, in particular.

In a step S4, for example by means of a laser, the concealed layer of the carrier layer structure, in particular the first electrically conductive contact layer 101 in the region of the cutouts 110, 111, is exposed. In this case, material of the buffer layer 104 may remain in inner walls of the cutouts 110, 111, such that an electrical insulation with respect to the second electrically conductive contact layer 103 and additionally a moisture barrier are thus made possible.

In a step S5, the electrically conductive electrode layer 20, the optically functional layer structure 22, the second electrically conductive electrode layer 23 and the thin-film encapsulation 24 are deposited successively on the buffer layer 104. In this case, the second electrically conductive electrode layer 23 is deposited over the whole area in such a way that material of the second electrically conductive electrode layer 23 is introduced in the cutouts 110, 111, such that an electrically conductive plated-through hole 112 is formed which enables an electrical connection between the second electrically conductive electrode layer 23 and the first electrically conductive contact layer 101.

The thin-film encapsulation 24 can optionally subsequently be removed by means of laser ablation, for example, in regions provided for this. Lateral contact regions can additionally be formed by means of laser cutting.

The optoelectronic component may be produced in a wafer assemblage. In particular, method steps S1 to S4 are carried out in the assemblage with a plurality of optoelectronic components. After the finished deposition of the individual layers of the optoelectronic components in the assemblage, the latter are released from the assemblage, by singulating. During singulating, steps can form between the individual layers of the optoelectronic component, such as are shown for example in the figure concerning method step S5.

As an alternative to the method discussed above, the cutouts 110, 111 of the carrier layer structure can be formed jointly or simultaneously in method step S2.

As a further alternative, in method steps S1 and S2 the carrier layer structure can be formed via the electrically insulating layer 102, for example a plastics film, which is coated on both sides with the first electrically conductive contact layer 101 and the second electrically conductive contact layer 103.

As a further alternative, the carrier layer structure can be formed by a plurality of electrically conductive contact layers that are electrically insulated from one another by means of an electrically insulating layer in each case. The optically functional layer structure 22 here is formed in a segmented fashion and/or a plurality of optically functional layer structures adjacent to one another are formed on the carrier layer structure and/or a plurality of optically functional layer structures arranged one above another are formed. Each optically functional layer structure or each segment is assigned a contact layer of the carrier layer structure, with which these are in each case electrically conductively connected via cutouts and plated-through holes.

As a further alternative, method steps S3 and S4 can be dispensed with. In this case, applying the electrically insulating buffer layer 104 and structuring it are obviated. In method step S5, the first electrically conductive electrode layer 20 is applied directly on the second electrically conductive contact layer 103 and is mechanically and electrically connected thereto. Moreover, the plated-through hole 112 is led in the cutouts 110, 111 in an electrically insulated manner with respect to the second electrically conductive contact layer 103, for example by means of an electrically insulating lacquer layer applied on inner walls of the cutouts 110, 111.

Alternative or additional embodiments of the optoelectronic component 10 have already been explained in connection with the embodiment concerning FIG. 2A and are of course correspondingly used in the production method, explained with reference to FIG. 5, without being explicitly presented again here.

FIG. 6 shows a detailed sectional illustration of a layer structure of one embodiment of an optoelectronic component, for example of the optoelectronic component 10 explained above, wherein the multilayered carrier layer structure is illustrated as carrier 12 in this detailed view and the electrical contacting of the optoelectronic component via the carrier layer structure is not illustrated. The optoelectronic component 10 can be formed as a top emitter and/or bottom emitter. If the optoelectronic component 10 is formed as a top emitter and bottom emitter, the optoelectronic component 10 can be referred to as an optically transparent component, for example a transparent organic light emitting diode.

The optoelectronic component 10 includes the carrier 12 and an active region above the carrier 12. A first barrier layer (not illustrated), for example a first barrier thin-film layer, can be formed between the carrier 12 and the active region. The active region includes the first electrically conductive electrode layer 20, the optically functional layer structure 22 and the second electrically conductive electrode layer 23. The thin-film encapsulation 24 is formed above the active region. The thin-film encapsulation 24 can be formed as a second barrier layer, for example as a second barrier thin-film layer. The covering body 38 is arranged above the active region and, if appropriate, above the thin-film encapsulation 24. The covering body 38 can be arranged on the thin-film encapsulation 24 by means of an adhesion medium layer 36, for example.

The active region is an electrically and/or optically active region. The active region is, for example, that region of the optoelectronic component 10 in which electric current for the operation of the optoelectronic component 10 flows and/or in which electromagnetic radiation is generated or absorbed.

The optically functional layer structure 22 may include one, two or more functional layer structure units and one, two or more intermediate layers between the layer structure units.

The carrier 12 may include a plastics film or a laminate including one or including a plurality of plastics films. The plastic may include one or a plurality of polyolefins. Furthermore, the plastic may include polyvinyl chloride (PVC), polystyrene (PS), polyester and/or polycarbonate (PC), polyethylene terephthalate (PET), polyethersulfone (PES) and/or polyethylene naphthalate (PEN). The carrier 12 can moreover include a metal, for example copper, silver, gold, platinum, iron, for example a metal compound, for example steel. The carrier 12 can be formed as a metal film or metal-coated film. The carrier 12 can be a part of a mirror structure or form the latter. The carrier 12 can have a mechanically rigid region and/or a mechanically flexible region or be formed in this way.

The first electrically conductive electrode layer 20 can be formed as an anode or as a cathode. The first electrically conductive electrode layer 20 can be formed as translucent or transparent. The first electrically conductive electrode layer 20 includes an electrically conductive material, for example metal and/or a transparent conductive oxide (TCO) or a layer stack of a plurality of layers including metals or TCOs. The first electrically conductive electrode layer 20 may include for example a layer stack of a combination of a layer of a metal on a layer of a TCO, or vice versa. One example is a silver layer applied on an indium tin oxide (ITO) layer (Ag on ITO) or ITO-Ag-ITO multilayers.

By way of example, Ag, Pt, Au, Mg, Al, Ba, In, Ca, Sm or Li, and compounds, combinations or alloys of these materials can be used as metal.

Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs.

The first electrically conductive electrode layer 20 may include, as an alternative or in addition to the materials mentioned: networks composed of metallic nanowires and nanoparticles, for example composed of Ag, networks composed of carbon nanotubes, graphene particles and graphene layers and/or networks composed of semiconducting nanowires. By way of example, the first electrically conductive electrode layer 20 may include or be formed from one of the following structures: a network composed of metallic nanowires, for example composed of Ag, which are combined with conductive polymers, a network composed of carbon nanotubes which are combined with conductive polymers, and/or graphene layers and composites. Furthermore, the first electrically conductive electrode layer 20 may include electrically conductive polymers or transition metal oxides.

The first electrically conductive electrode layer 20 can have for example a layer thickness in a range of 10 nm to 500 nm, for example of 25 nm to 250 nm, for example of 50 nm to 100 nm.

The first electrically conductive electrode layer 20 can have a first electrical terminal, to which a first electrical potential can be applied. The first electrical potential can be provided by an energy source (not illustrated), for example by a current source or a voltage source. Alternatively, the first electrical potential can be applied to the carrier 12 and the first electrically conductive electrode layer 20 can be supplied indirectly via the carrier 12. The first electrical potential can be for example the ground potential or some other predefined reference potential.

The optically functional layer structure 22 may include a hole injection layer, a hole transport layer, an emitter layer, an electron transport layer and/or an electron injection layer.

The hole injection layer can be formed on or above the first electrically conductive electrode layer 20. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)-benzidine); beta-NPB (N,N′-bis(naphthalen-2-yl)-N,N′-bis-(phenyl)benzidine); TPD (N,N′-bis(3-methylphenyl)-N,N′-bis-(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD (N,N′-bis(3-methyl-phenyl)-N,N′-bis(phenyl)-9,9-dimethylfluorene); DMFL-NPB (N,N′-bis(naphthalen-1-yl)-N,N′-bis(phenyl)-9,9-dimethyl-fluorene); DPFL-TPD (N,N′-bis(3-methylphenyl)-N,N′-bis-(phenyl)-9,9-diphenylfluorene); DPFL-NPB (N,N′-bis-(naphthalen-1-yl)-N,N′-bis(phenyl)-9,9-diphenylfluorene); spiro-TAD (2,2′,7,7′-tetrakis(N,N-diphenylamino)-9,9′-spiro-bifluorene); 9,9-bis[4-(N,N-bisbiphenyl-4-ylamino)phenyl]-9H-fluorene; 9,9-bis[4-(N,N-bisnaphthalen-2-ylamino)phenyl]-9H-fluorene; 9,9-bis[4-(N,N′-bisnaphthalen-2-yl-N,N′-bisphenyl-amino)phenyl]-9H-fluorene; N,N′-bis(phenanthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)-9,9-spirobifluorene; di[4-(N,N-ditolylamino)phenyl]-cyclohexane; 2,2′,7,7′-tetra(N,N-ditolyl)aminospiro-bifluorene; and/or N,N,N′,N′-tetranaphthalen-2-ylbenzidine.

The hole injection layer can have a layer thickness in a range of approximately 10 nm to approximately 1000 nm, for example in a range of approximately 30 nm to approximately 300 nm, for example in a range of approximately 50 nm to approximately 200 nm.

The hole transport layer can be formed on or above the hole injection layer. The hole transport layer may include or be formed from one or a plurality of the following materials: NPB (N,N′-bis(naphthalen-1-yl)-N,N′-bis(phenyl)benzidine); beta-NPB (N,N′-bis(naphthalen-2-yl)-N,N′-bis(phenyl)-benzidine); TPD (N,N′-bis(3-methylphenyl)-N,N′-bis(phen-yl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD (N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(N,N-diphenylamino)-9,9′-spirobifluorene); 9,9-bis[4-(N,N-bisbiphenyl-4-yl-amino)phenyl]-9H-fluorene; 9,9-bis[4-(N,N-bisnaphthalen-2-ylamino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)-benzidine; 2,7-bis[N,N-bis(9,9-spirobifluoren-2-yl)amino]-9,9-spirobifluorene; 2,2′-bis[N,N-bis(biphenyl-4-yl)amino]-9,9-spirobifluorene; 2,2′-bis(N,N-diphenylamino)-9,9-spiro-bifluorene; di[4-(N,N-ditolylamino)phenyl]cyclohexane; 2,2′,7,7′-tetra(N,N-ditolyl)aminospirobifluorene; and N,N,N′,N′-tetranaphthalen-2-ylbenzidine.

The hole transport layer can have a layer thickness in a range of approximately 5 nm to approximately 50 nm, for example in a range of approximately 10 nm to approximately 30 nm, for example approximately 20 nm.

The one or a plurality of emitter layers, for example including fluorescent and/or phosphorescent emitters, can be formed on or above the hole transport layer. The emitter layer may include organic polymers, organic oligomers, organic monomers, organic small, non-polymeric molecules (“small molecules”) or a combination of these materials. The emitter layer may include or be formed from one or a plurality of the following materials: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)3 (tris(2-phenylpyridine) iridium III), red phosphorescent Ru (dtb-bpy) 3*2(PF6) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited for example by means of thermal evaporation. Furthermore, polymer emitters can be used which can be deposited for example by means of a wet-chemical method, such as, for example, a spin coating method. The emitter materials can be embedded in a suitable manner in a matrix material, for example a technical ceramic or a polymer, for example an epoxy; or a silicone.

The first emitter layer can have a layer thickness in a range of approximately 5 nm to approximately 50 nm, for example in a range of approximately 10 nm to approximately 30 nm, for example approximately 20 nm.

The emitter layer may include emitter materials that emit in one color or in different colors (for example blue and yellow or blue, green and red). Alternatively, the emitter layer may include a plurality of partial layers which emit light of different colors. By means of mixing the different colors, the emission of light having a white color impression can result. Alternatively or additionally, provision can be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The electron transport layer can be formed, for example deposited, on or above the emitter layer. The electron transport layer may include or be formed from one or a plurality of the following materials: NET-18; 2,2′,2″-(1,3,5-benzinetriyl)tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxy-quinolinolato lithium; 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)-aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadi-azo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)-borane; 1-methyl-2-(4-(naphthalen-2-yl)phenyl)-1H-imidazo-[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclo-pentadiene unit.

The electron transport layer can have a layer thickness in a range of approximately 5 nm to approximately 50 nm, for example in a range of approximately 10 nm to approximately 30 nm, for example approximately 20 nm.

The electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]-phenanthroline; phenyldipyrenylphosphine oxide; naphthalenetetracarboxylic dianhydride or the imides thereof; perylenetetracarboxylic dianhydride or the imides thereof; and substances based on silols including a silacyclo-pentadiene unit.

The electron injection layer can have a layer thickness in a range of approximately 5 nm to approximately 200 nm, for example in a range of approximately 20 nm to approximately 50 nm, for example approximately 30 nm.

In the case of an optically functional layer structure 22 including two or more optically functional layer structure units, corresponding intermediate layers can be formed between the optically functional layer structure units. The optically functional layer structure units can be formed in each case individually by themselves in accordance with a configuration of the optically functional layer structure 22 explained above. The intermediate layer can be formed as an intermediate electrode. The intermediate electrode can be electrically connected to an external voltage source. The external voltage source can provide a third electrical potential, for example, at the intermediate electrode. However, the intermediate electrode can also have no external electrical terminal, for example by the intermediate electrode having a floating electrical potential.

The optically functional layer structure unit can have for example a layer thickness of a maximum of approximately 3 μm, for example a layer thickness of a maximum of approximately 1 μm, for example a layer thickness of a maximum of approximately 300 nm.

The optoelectronic component 10 can optionally include further functional layers, for example arranged on or above the one or the plurality of emitter layers or on or above the electron transport layer. The further functional layers can be for example internal or external coupling-in/coupling-out structures that can further improve the functionality and thus the efficiency of the optoelectronic component 10.

The second electrically conductive electrode layer 23 can be formed in accordance with one of the configurations of the first electrically conductive electrode layer 20, wherein the first electrically conductive electrode layer 20 and the second electrically conductive electrode layer 23 can be formed identically or differently. The second electrically conductive electrode layer 23 can be formed as an anode or as a cathode. The second electrically conductive electrode layer 23 can have a second electrical terminal, to which a second electrical potential can be applied. The second electrical potential can be provided by the same energy source as, or a different energy source than, the first electrical potential. The second electrical potential can be different than the first electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The thin-film encapsulation 24 can be formed as a translucent or transparent layer. The thin-film encapsulation 24 forms a barrier against chemical impurities or atmospheric substances, in particular against water (moisture) and oxygen. In other words, the thin-film encapsulation 24 is formed in such a way that substances that can damage the optoelectronic component, for example water, oxygen or solvent, cannot penetrate through it or at most very small proportions of said substances can penetrate through it. The thin-film encapsulation 24 can be formed as an individual layer, a layer stack or a layer structure.

The thin-film encapsulation 24 may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenyleneterephthalamide), nylon 66, and mixtures and alloys thereof.

The thin-film encapsulation 24 can have a layer thickness of approximately 0.1 nm (one atomic layer) to approximately 1000 nm, for example a layer thickness of approximately 10 nm to approximately 100 nm, for example approximately 40 nm. The thin-film encapsulation 24 may include a high refractive index material, for example one or a plurality of material(s) having a high refractive index, for example having a refractive index of 1.5 to 3, for example of 1.7 to 2.5, for example of 1.8 to 2.

If appropriate, the first barrier layer can be formed on the carrier 12 in a manner corresponding to a configuration of the thin-film encapsulation 24.

The thin-film encapsulation 24 can be formed for example by means of a suitable deposition method, e.g. by means of an atomic layer deposition (ALD) method, e.g. a plasma enhanced atomic layer deposition (PEALD) method or a plasmaless atomic layer deposition (PLALD) method, or by means of a chemical vapor deposition (CVD) method, e.g. a plasma enhanced chemical vapor deposition (PECVD) method or a plasmaless chemical vapor deposition (PLCVD) method, or alternatively by means of other suitable deposition methods.

Optionally, a coupling-in or coupling-out layer can be formed for example as an external film (not illustrated) on the carrier 12 or as an internal coupling-out layer (not illustrated) in the layer cross section of the optoelectronic component 10. The coupling-in/-out layer may include a matrix and scattering centers distributed therein, wherein the average refractive index of the coupling-in/-out layer is greater than the average refractive index of the layer from which the electromagnetic radiation is provided. Furthermore, in addition, one or a plurality of antireflection layers can be formed.

The adhesion medium layer 36 may include adhesive and/or lacquer, for example, by means of which the covering body 38 is arranged, for example adhesively bonded, on the thin-film encapsulation 24, for example. The adhesion medium layer 36 can be formed as transparent or translucent. The adhesion medium layer 36 may include for example particles which scatter electromagnetic radiation, for example light-scattering particles. As a result, the adhesion medium layer 36 can act as a scattering layer and lead to an improvement in the color angle distortion and the coupling-out efficiency.

The light-scattering particles provided can be dielectric scattering particles, for example composed of a metal oxide, for example silicon oxide (SiO₂), zinc oxide (ZnO), zirconium oxide (ZrO₂), indium tin oxide (ITO) or indium zinc oxide (IZO), gallium oxide (Ga₂Oₓ), aluminum oxide, or titanium oxide. Other particles may also be suitable provided that they have a refractive index that is different than the effective refractive index of the matrix of the adhesion medium layer 36, for example air bubbles, acrylate, or hollow glass beads. Furthermore, by way of example, metallic nanoparticles, metals such as gold, silver, iron nanoparticles, or the like can be provided as light-scattering particles.

The adhesion medium layer 36 can have a layer thickness of greater than 1 μm, for example a layer thickness of a plurality of μm. In various embodiments, the adhesive can be a lamination adhesive.

The adhesion medium layer 36 can have a refractive index that is less than the refractive index of the covering body 38. The adhesion medium layer 36 may include for example a low refractive index adhesive such as, for example, an acrylate having a refractive index of approximately 1.3. However, the adhesion medium layer 36 can also include a high refractive index adhesive which for example includes high refractive index, non-scattering particles and has a layer-thickness-averaged refractive index that approximately corresponds to the average refractive index of the optically functional layer structure 22, for example in a range of approximately 1.6 to 2.5, for example of 1.7 to approximately 2.0.

A so-called getter layer or getter structure, i.e. a laterally structured getter layer, can be arranged (not illustrated) on or above the active region. The getter layer can be formed as translucent, transparent or opaque. The getter layer may include or be formed from a material that absorbs and binds substances that are harmful to the active region. A getter layer may include or be formed from a zeolite derivative, for example. The getter layer can have a layer thickness of greater than 1 μm, for example a layer thickness of a plurality of μm. In various embodiments, the getter layer may include a lamination adhesive or be embedded in the adhesion medium layer 36.

The covering body 38 can be formed for example by a glass body, a metal film or a sealed plastics film covering body. The covering body 38 can be arranged on the thin-film encapsulation 24 or the active region for example by means of frit bonding (glass frit bonding/glass soldering/seal glass bonding) by means of a conventional glass solder in the geometrical edge regions of the optoelectronic component 10. The covering body 38 can have for example a refractive index (for example at a wavelength of 633 nm) of for example 1.3 to 3, for example of 1.4 to 2, for example of 1.5 to 1.8.

The disclosure is not restricted to the embodiments indicated. By way of example, the optoelectronic component 10 can be formed in a segmented fashion. Alternatively or additionally, a plurality of optoelectronic components 10 can be arranged alongside one another to form an optoelectronic assembly.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component comprising:
a first electrically conductive contact layer,
an electrically insulating layer above the first electrically conductive contact layer,
a second electrically conductive contact layer above the electrically insulating layer,
a first electrically conductive electrode layer above the second electrically conductive contact layer,
at least one optically functional layer structure above the first electrically conductive electrode layer, and
a second electrically conductive electrode layer above the optically functional layer structure,
wherein
the second electrically conductive contact layer has a first cutout,
the electrically insulating layer has a second cutout, which overlaps the first cutout,
an electrically conductive plated-through hole is arranged in the first cutout and in the second cutout, said electrically conductive plated-through hole being led to the first electrically conductive contact layer, and
the electrically conductive plated-through hole is electrically insulated with respect to the second electrically conductive contact layer.

2. The optoelectronic component as claimed in claim 1, wherein
the first electrically conductive electrode layer is electrically conductively connected to the second electrically conductive contact layer, and
the second electrically conductive electrode layer is electrically conductively connected to the first electrically conductive contact layer via the electrically conductive plated-through hole.

3. The optoelectronic component as claimed in claim 2, wherein the electrically conductive plated-through hole and the second electrically conductive electrode layer are formed in an integral fashion.

4. The optoelectronic component as claimed in claim 1, wherein the first electrically conductive contact layer, the electrically insulating layer and the second electrically conductive contact layer are formed as a film laminate.

5. The optoelectronic component as claimed in claim 1, wherein a lacquer layer for electrical insulation is arranged between the electrically conductive plated-through hole and the second electrically conductive contact layer.

6. The optoelectronic component as claimed in claim 1, wherein
the first electrically conductive contact layer has a third cutout, the electrically insulating layer has a fourth cutout, which overlaps the third cutout, and
in the third cutout and in the fourth cutout an external electrically conductive connection is led to the second electrically conductive contact layer, which is electrically insulated with respect to the first electrically conductive contact layer.

7. The optoelectronic component as claimed in claim 1, further comprising
at least one third electrically conductive electrode layer above the second electrically conductive electrode layer,
at least one third electrically conductive contact layer above the second electrically conductive contact layer,
at least one second electrically insulating layer between the second electrically conductive contact layer and the third electrically conductive contact layer,
at least one further cutout and at least one further electrically conductive plated-through hole.

8. The optoelectronic component as claimed in claim 1, wherein
at least one of the electrode layers and/or the optically functional layer structure are/is laterally segmented, and
a plurality of electrically conductive contact layers, electrically isolated from one another, for electrically contacting the individual lateral segments are formed vertically one above another.

9. The optoelectronic component as claimed in claim 8, wherein
at least one of the electrically conductive contact layers for electrical contacting is assigned to each electrode layer and is electrically connected thereto.

10. A method for manufacturing an optoelectronic component comprising:
forming a first electrically conductive contact layer,
forming an electrically insulating layer above the first electrically conductive contact layer,
forming a second electrically conductive contact layer above the electrically insulating layer,
forming a first cutout in the second electrically conductive contact layer,
forming a second cutout the electrically insulating layer, which overlaps the first cutout,
forming an electrically conductive plated-through hole in the first cutout and in the second cutout, wherein the electrically conductive plated-through hole is electrically conductively connected to the first electrically conductive contact layer and is electrically insulated from the second electrically conductive contact layer,
forming a first electrically conductive electrode layer above the second electrically conductive contact layer,
forming at least one optically functional layer structure above the first electrically conductive electrode layer, and
forming a second electrically conductive electrode layer above the optically functional layer structure.

11. The method as claimed in claim 10, wherein the first cutout and the second cutout are formed simultaneously.

12. The method as claimed in claim 10, wherein the second electrically conductive electrode layer and the electrically conductive plated-through hole are formed simultaneously.

13. The method as claimed in claim 10, wherein the first electrically conductive contact layer, the electrically insulating layer and the second electrically conductive contact layer are formed by the electrically insulating layer being provided and coated on both sides with the first electrically conductive contact layer and the second electrically conductive contact layer.

14. The method as claimed in claim 10, wherein the first electrically conductive contact layer, the electrically insulating layer and the second electrically conductive contact layer are formed by one of the electrically conductive contact layers being provided and the electrically insulating layer being formed on the electrically conductive contact layer provided, and the other of the electrically conductive contact layers subsequently being formed on the electrically insulating layer.

15. The method as claimed in claim 10, wherein
at least one second electrically insulating layer is formed above the second electrically conductive contact layer,
at least one third electrically conductive contact layer is formed above the second electrically insulating layer,
at least one further cutout and at least one further electrically conductive plated-through hole are formed, and
at least one third electrically conductive electrode layer is formed above the second electrically conductive electrode layer.

16. The method as claimed in claim 10, wherein
at least one of the electrode layers and/or the optically functional layer structure are/is laterally segmented, and
a plurality of electrically conductive contact layers, electrically isolated from one another, for electrically contacting the individual lateral segments are formed vertically one above another.

17. An optoelectronic component comprising
a first electrically conductive contact layer,
an electrically insulating layer above the first electrically conductive contact layer,
a second electrically conductive contact layer above the electrically insulating layer,
a first electrically conductive electrode layer above the second electrically conductive contact layer,
at least one optically functional layer structure above the first electrically conductive electrode layer, and
a second electrically conductive electrode layer above the optically functional layer structure,
wherein
the second electrically conductive contact layer has a first cutout,
the electrically insulating layer has a second cutout, which overlaps the first cutout,
an electrically conductive plated-through hole is arranged in the first cutout and in the second cutout, said electrically conductive plated-through hole being led to the first electrically conductive contact layer and being electrically connected to the first electrically conductive contact layer, and
the electrically conductive plated-through hole is electrically insulated with respect to the second electrically conductive contact layer,
wherein the first electrically conductive electrode layer is electrically conductively connected to the second electrically conductive contact layer,
wherein the second electrically conductive electrode layer is electrically conductively connected to the first electrically conductive contact layer via the electrically conductive plated-through hole, and
wherein the electrically conductive plated-through hole and the second electrically conductive electrode layer are formed in an integral fashion.
